(19) United States
(12) Patent Application Publication
(10) Pub. No.: US 2014/0263952 A1
(43) Pub. Date: Sep. 18, 2014

(54) HIGH PERFORMANCE DIGITAL IMAGING SYSTEM

(71) Applicant: PERKINELMER HOLDINGS, INC., Waltham, MA (US)

(72) Inventors: Farhad TAGHIBAKHSH, Santa Clara, CA (US); Kai ZHANG, Saratoga, CA (US); Richard AUFRICHTIG, Palo Alto, CA (US)

(73) Assignee: PERKINELMER HOLDINGS, INC., Waltham, MA (US)

(21) Appl. No.: 13/831,467

(22) Filed: Mar. 14, 2013

(51) Int. Cl. H04N 5/378

(52) U.S. Cl. CPC H04N 5/378
USPC 250/208.1; 250/214 DC

(57) ABSTRACT

A sensor array including sensor pixels is disclosed. A sensor pixel includes a detector and a readout circuit operatively coupled to the detector. The readout circuit includes at least one readout element formed from an amorphous metal oxide alloy semiconductor. Also disclosed is an image detector panel including a sensor array with sensor pixels arranged into rows and columns. The image detector panel includes a gate driver module configured to address rows of the sensor array, and a multiplexing module configured to select columns of the sensor array and multiplex signals from the sensor pixels. The gate driver module and the multiplexing module include elements formed from an amorphous metal oxide alloy semiconductor.

### BACKGROUND

1. Field

This application relates generally to sensor pixels and sensor arrays, and, more specifically, to sensor pixels and sensor arrays having readout circuitry that consists of thin film transistors (TFT) formed from an amorphous metal oxide (a-MO) alloy semiconductor.

2. Description of the Related Art

A sensor pixel consists of a detector and an electronic readout circuit. The sensor pixel is operated via connection to peripheral circuits (biasing, addressing, readout and digitizer circuitries). Individual sensor pixels can be arranged in a matrix to form an array. In imaging applications, the signal from each sensor pixel in the array can be read and arranged (i.e., multiplexed) and digitized to generate a digital electronic image.

Sensor pixels may be passive or active. In a passive pixel sensor (PPS), signal charge is accumulated on the sensor pixel during an integration cycle and is transferred to an external charge amplifier during a readout/reset cycle. The transferred charge is converted to an equivalent voltage in the charge amplifier and is then further processed. In an active pixel sensor (APS), amplification of the signal is performed on the pixel in the readout circuit. The amplification may be performed, for example, by an on-pixel transistor amplifier that converts a detector voltage to an equivalent output current to be further processed in external circuitry.

In current X-ray imaging applications, both the detector and transistors in the readout circuitry of a sensor pixel are typically made using amorphous silicon (a-Si). While a-Si is a suitable material for the detector because of its response to photons with energies in the visible spectrum, it is undesirable as a transistor material. Transistors made from a-Si have low electron mobility, which reduces the speed at which the transistors transfer electric signals. The ability to transfer signals quickly is especially important in imaging applications using very large arrays. Slow transfer times increase the total amount of time required to read the signals from all the pixels in the array, which reduces the number of frame images that can be captured per second (i.e., reduced frame rate or increased frame time). Shorter frame times are especially desirable for live imaging or reducing the total imaging time in certain imaging modalities that require multiple frames such as tomosynthesis or computed tomography.

The slow speed of a-Si transistors makes it unfeasible to integrate circuitry for driving the sensor pixel array and multiplexing the obtained pixel values on the same panel containing the sensor array. Thus, driving and multiplexing circuitry is typically located off of the panel. Integration, however, is very desirable to minimize the cost and volume of the off-panel electronic modules required to operate the array.

Attempts at using other materials have been made. For example, use of indium gallium zinc oxide (IGZO) in place of a-Si in PPS arrays for X-ray imaging has been reported in Lujan et al., IEEE ELECTRON DEVICE LETTERS, VOL. 33, No. 5, May 2012. Basic 3-transistor APSs using IGZO to improve the imaging performance have also been described in Yamada et al., US 2012/0175618 A1 and US 2013/0313103 A1.

Still there remains an opportunity to improve sensor array performance in various ways such as improving the speed of transistors, employing novel pixel readout circuits, and/or integrating driving circuitry on the panel along the sensor array.

### SUMMARY

This disclosure proposes novel active pixel sensor architectures based on charge-gated TFTs made from an amorphous metal oxide (a-MO) alloy semiconductor such as amorphous IGZO (a-IGZO) for improved imaging performance. In place of a charge-gated thin film transistor, a thin-film transistor formed from a-MO may be coupled to a capacitor to achieve a similar effect. A plurality of sensor pixels may be used to form an imaging array. Also disclosed is an image detector panel including a sensor array with sensor pixels arranged into rows and columns. The image detector panel includes a gate driver module configured to address rows of the sensor array, and a multiplexing module configured to select columns of the sensor array and multiplex signals from the sensor pixels. The gate driver module and the multiplexing module may include elements formed from a-MO semiconductor.

In one embodiment, a sensor pixel includes a detector and a readout circuit operatively coupled to the detector. The readout circuit includes a charge-gated TFT formed from a-MO. The charge-gated TFT may be configured in active mode to amplify a signal representative of a signal produced by the detector. The detector of the sensor pixel may be an organic photodiode or an amorphous silicon (a-Si) photodiode, or a photo sensor formed from a material selected from the group consisting of mercuric iodide (HgI), cadmium telluride (CdTe), and amorphous selenium (a-Se). In some embodiments, the readout circuit includes an output terminal, and the sensor pixel is configured to generate, at the pixel output terminal, a signal representative of the signal produced by the detector. The charge-gated TFT may be configured to generate a signal representative of the signal produced by the detector in response to an input signal applied to a voltage gate of the charge-gated TFT. In some embodiments, the readout circuit includes a node and a switch transistor such that a signal at the node is transferred to a charge gate of the charge-gated TFT in response to the switch transistor being switched on. The charge-gated TFT may be formed from a-IGZO.

In another embodiment, the readout circuit includes a TFT coupled to a capacitor. The TFT is formed from a-MO semiconductor. The coupling capacitor is responsive to an input signal which causes the TFT to generate an output signal representative of a signal produced by the detector. The readout circuit may further comprise a switch transistor configured to transfer an output signal of the TFT to an output terminal of the pixel in response to the switch transistor being turned on.

In one embodiment, a sensor array includes a plurality of sensor pixels. The sensor pixels may be configured in a two dimensional array having a plurality of rows and a plurality of columns. The array may be configured to output a signal from an addressed sensor pixel at an output terminal in response to a control signal addressing the addressed sensor pixel.

In yet another embodiment, an image detector panel includes a sensor array, a gate driver module, and a multiplexing module. The gate driver module is configured to address the rows, while the multiplexing module is configured to select columns and to multiplex pixel signals from the sensor pixels. Furthermore, the gate driver module and the multiplexing module each have a plurality of elements formed from a-MO. In one embodiment, the gate driver module elements and the multiplexing module elements are TFTs formed from a-IGZO.

An image detector panel may include a plurality of gate driver modules, wherein each of the gate driver modules is configured to address a subset of the rows of the sensor array. The image detector panel may also include a plurality of multiplexer modules, wherein each of the multiplexer modules is configured to multiplex the sensor values from the sensor pixels in a subset of the columns of the sensor array.

### DESCRIPTION OF THE FIGURES

FIG. 1 depicts a circuit diagram of an exemplary image sensor pixel having a photodiode photo sensor and a charge-gated TFT;

FIG. 2 depicts a diagram of exemplary control signal pulses and the output signal for a single sample (SS) readout driving scheme;

FIG. 3 depicts a diagram of exemplary control signals and the output signal for a correlated double sampling (CDS) readout driving scheme;

FIG. 4 depicts a circuit diagram of an exemplary image sensor pixel having a photodiode photo sensor, three TFTs, and a capacitor;

FIG. 5 depicts a circuit diagram of an exemplary image sensor pixel having a photodiode photo sensor, four TFTs, and a capacitor;

FIG. 6 depicts a circuit diagram of an exemplary image sensor pixel having a photoconductor photo sensor, three film transistors, and two capacitors;

FIG. 7 depicts a circuit diagram of an exemplary image sensor pixel having a photoconductor photo sensor, four TFTs, and two capacitors;

FIGS. 8A-B depict a circuit diagram of an exemplary active pixel sensor with two TFTs and a photoconductor sensor, and an example of control signals and the output for a single sample (SS) readout driving scheme;

FIG. 9 depicts a schematic diagram of an exemplary active pixel sensor consisting of a photo sensor and a high mobility TFT active readout circuit;

FIG. 10 depicts a schematic diagram of an image sensor array consisting of a two-dimensional arrangement of image sensor pixels;

FIG. 11A depicts a diagram of an exemplary image detector panel;

FIG. 11B depicts a diagram of an exemplary gate driver;

FIG. 11C depicts an exemplary TFT gate driver implemented using D-type flip flops and pull-up pull-down stages;

FIG. 11D depicts exemplary D-type flip flop and pull-up pull-down circuits implemented using TFTs;

FIG. 11E depicts a diagram of a multiplexing circuit based on TFT gate drivers and TFT select switches;

FIGS. 12A-B depict exemplary block diagrams of signal processing and analog to digital conversion (ADC) circuits;

FIG. 13A depicts a graph of simulated offset noise electrons for an array of a-Si passive pixel sensors and an array of a-MO active pixel sensors;

FIG. 13B depicts a graph of simulated output voltage of a sensor pixel readout circuit made from a-Si TFTs and a sensor pixel readout circuit made from a-MO TFTs;

FIG. 13C depicts a graph of simulated output current of a sensor pixel readout circuit made from a-Si TFTs and a sensor pixel readout circuit made from a-MO TFTs; and

FIGS. 14A-B depict schematic diagrams of exemplary embodiments of multi-layered X-ray image detectors.

The figures depict embodiments of the present invention for purposes of illustration only. One skilled in the art will readily recognize from the following discussion that alternative embodiments of the structures and methods illustrated herein can be employed without departing from the principles of the invention described herein.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

Improving the performance of pixel readout circuits in large area digital image detectors may significantly improve the overall performance of an X-ray image detector. This disclosure presents various pixel readout circuits for a hybrid technology for making image sensor pixels and image detectors where the photo-detecting sensor and the readout circuitry elements are formed from different materials. For example, an image sensor pixel may use a-Si to form a photodiode sensor and use a-MO such as a-IGZO to form TFTs in the readout circuit. Amorphous metal oxide alloy semiconductors such as a-IGZO have better electrical properties than a-Si including higher mobility, better stability, and lower leakage. The use of elements using high mobility materials, such as a-MO TFTs, further provide the possibility of integrating driving and multiplexing circuits with the image sensor, i.e., fabricating all or part of the peripheral circuits required for the operation of an image sensor on the same substrate as the image sensor array.

### 1. Sensor Pixel Configurations

FIG. 1 depicts a circuit diagram of one embodiment of a sensor pixel. Sensor pixel 100 includes photodiode 110, readout circuit 120, output 130, biasing voltages VB1, VB2 and VB3, control lines 140, and data line 150. Photodiode 110 is reverse biased, and therefore converts incident light photons to an electric signal, which is converted to an equivalent representative voltage or current at output 130 by applying proper control signals to readout circuit 120 using control lines 140. Photodiode 110 may be formed from, for example, a-Si or organic materials. Readout circuit 120 includes charge-gated TFT (CGT) 122, which acts as a switched amplifier. All transistor elements of the readout circuit, including CGT 122, may be high mobility TFTs made of a-MO such as a-IGZO. Various alloy compositions of the a-MO may be used. For example, a-IGZO having In:Ga:Zn component ratios of 2:2:1, 4:2:1, 2:1:1, or the like, may be used.

FIG. 2 depicts a diagram of exemplary control signal pulses and output signal for a single sample (SS) readout driving scheme using sensor pixel 100. There are three phases associated with operation of the pixel circuit: Phase 1 is for resetting the pixel circuit, Phase 2 is for photon integration, and Phase 3 is for readout. In Phase 1, both transistors T1 124 and T2 126 are turned ON by applying voltage pulses to control lines 1 and 2, which sets the voltages of nodes SN1 128 and SN2 123 both to VB3 such that the voltage across photodiode 110 becomes VB1-VB3. In Phase 2 all the transistors are OFF. During Phase 2 integration, absorption of photons by photodiode 110 reduces the voltage across photodiode 110, and reduces the voltage of SN1 128. In Phase 3, T2 126 is turned ON by applying a voltage pulse to control line 2. As a result, the voltage of SN2 123 (i.e., the voltage at the charge gate of the CGT 122) drops to that of SN1 128 (i.e., the voltage drop across photodiode 110 now appears on SN2 123). Thus, the voltage at photodiode 110 is effectively transferred to SN2 123. Then the voltage pulse applied to control line 3 adds a fixed amount of voltage to SN2 123 through capacitive coupling of the voltage gate of CGT 122, and increases the voltage of SN2 123 above VB3, which turns CGT 1220N. The drain current of CGT 122 flows to output 130 according to the gate-source voltage of CGT 122, i.e., depending on the voltage of SN2 123, which holds the voltage drop across photodiode 110 during photon integration. VB2 is the drain biasing voltage of CGT 122 and the voltage VB3 is preferably at a level such that CGT 122 is OFF when VB3 alone is applied to the charge gate of CGT 122.

FIG. 3 depicts another example of a driving signal operation for the pixel circuit shown in FIG. 1 which is known as correlated double sampling (CDS). The operation in the first two phases is similar to that shown in FIG. 2. The CDS readout scheme is implemented in the readout phase, Phase 3, where a first sample (Si, or an offset value) is readout by applying a pulse to control line 3 when the voltage at SN2 123 is still the reset value VB3, or before T2 126 is turned ON. A second sample (S2) is taken after T2 126 is turned ON and the voltage drop across the photodiode 110 appears at SN2 123. The difference between the two samples S1 and S2 is related to the voltage drop across the photodiode 110 as the result of absorbed photons in Phase 2. As in the SS scheme, the voltage VB3 should be at a level that when applied to the charge gate of CGT 122, the transistor is OFF.

FIG. 4 shows a variation of the pixel circuit shown in FIG. 1, where the CGT in the readout circuit is replaced (or represented) by a capacitor and a transistor. Photo sensor 410 is a photodiode. In sensor pixel 400, the common electrode between the gate of T3 422 and capacitor C1 425 acts as a charge gate, while the other electrode of C1 425 acts as the gate of a CGT. Control line 3 is coupled to C1 425, and the sense node voltage of SN2 423 is the gate voltage of T3 422. The pixel circuit can operate in single sample (SS) readout mode as shown in FIG. 2, or CDS mode as shown in FIG. 3. In readout phase, Phase 3, the voltage pulse applied to control line 3 adds a fixed amount of voltage to SN2 423 through capacitive coupling via C1 425, and turns T3 422 ON. The drain current of T3 422 flows to the output according to the gate-source voltage, i.e., depending on the voltage of SN2 423. The voltage VB3 is preferably at a level that when applied to the gate of T3 422 the transistor is OFF. Alternatively, VB3 may be connected to output 430 if the threshold voltage of T3 is sufficiently high to keep T3 422 OFF during photon integration.

FIG. 5 discloses another embodiment of the pixel circuit in which use of an additional transistor, T4 527, eliminates the constraint on VB3 described in the embodiments discussed above. Here, because the gate voltage of T4 527 is directly accessible through control line 3, T4 527 can be turned OFF independent of the voltage of SN2 523. Thus, this readout circuit provides more flexibility on the choice of biasing voltages. For example, VB3 can be positive such that T3 522 will turn ON as soon as T4 527 is turned on during readout phase. Capacitor C1 525 capacitively couples the readout pulse of control line 3 to the gate of T3 522 for faster ON/OFF switching. Without C1 525, in order for T3 522 to turn ON, the source voltage of T3 522 must drop so that its gate-source voltage increases beyond its threshold voltage. However, with C1 525, the gate voltage also increases helping the gate-source voltage to increase faster. The pixel circuit may be driven using SS or CDS readout schemes. Use of positive voltages for VB3 also provides the possibility of connecting VB3 and VB2 together to reduce the number of biasing voltages for the pixel array from three to two. Another option is to connect VB3 to the data line 550 which preferably has a low voltage, for example, around zero.

Instead of a photodiode, a photoconductor photo sensor may be used. FIG. 6 depicts a diagram of an embodiment of a sensor pixel employing a photoconductor photo-sensor. The photoconductor 610 may be made from, for example, mercuric iodide (HgI), cadmium telluride (CdTe), or amorphous selenium (a-Se). The readout circuit is similar to the readout circuits disclosed in FIG. 1 and FIG. 4, except that the readout circuit has an additional capacitor C2 629. C2 629 represents the storage capacitance at node SN1 which may or may not physically exist depending on the actual capacitance of the node. If the effective capacitance of the node is not adequate for holding the sensor charge produced as the result of photon absorption in Phase 2, a physical capacitance is needed at the node. Similar to the embodiment presented in FIG. 4, VB3 can be connected to the output 630 if the threshold voltage of T3 622 is sufficiently large to keep T3 622 OFF during photon integration. The pixel circuit may be driven using SS or CDS readout schemes. C1 625 and T3 622 may also be replaced by a CGT.

Similar to the embodiment disclosed in FIG. 5, a fourth transistor may be used to eliminate the constraint on VB3. In the embodiment disclosed in FIG. 7, a photoconductor photo-sensor is used in conjunction with a four-transistor active readout circuit, in which the gate voltage of T4 727 is directly accessible by control line 3. Transistor T4 727 can be turned OFF independent of the voltage level of SN2 723. This readout circuit provides more flexibility on the choice of biasing voltages. For example, VB3 may be positive such that T3 722 turns ON as soon as T4 727 is turned on during readout phase. Capacitor C1 725 capacitively couples the readout pulse at control line to the gate of T3 722 for faster ON/OFF switching. Without C1 725, in order for T3 722 to turn ON, the source voltage must drop so that the gate-source voltage increases beyond the threshold voltage. However, with C1 725, the gate voltage also increases helping the gate-source voltage increase faster. The pixel circuit may be driven using SS or CDS readout schemes such as, for example, the schemes shown in FIG. 2 and FIG. 3. Use of positive voltages for VB3 provides the possibility of connecting VB3 and VB2 together to use only two biasing voltages for the pixel array instead of three. Alternatively, VB3 may be connected to the data line which preferably has a low voltage, for example, around zero.

In the embodiment depicted in FIG. 8A only two transistors are used. Capacitor C1 829 acts as the storage capacitor as well as the feed through capacitance allowing T2 826 to switch ON and OFF by applying readout pulses to control line 2. Pixel circuit 800 is compact for use in high resolution sensor arrays and can be driven only by a SS readout scheme according to FIG. 8B. In Phase 1, T1 824 is turned ON which discharges stored charge on C1 829. In Phase 2, photon integration on photoconductor 810 charges up C1 829 causing a voltage difference across C1 829. In Phase 3, the pulse applied to control line 2 increases the voltage of SN1 828 because of capacitive coupling through C1 829. This causes T2 826 to turn ON which results in flowing of drain current to the output.

### 2. Sensor Arrays

FIG. 9 illustrates image sensor pixel 900 comprised of photo sensor 910 and high mobility TFT active readout circuit 920 according to one embodiment. Photo sensor 910 may be a photodiode made from, for example, a-Si or organic semiconductor materials, or a photo-conductor made from, for example, HgI, CdTe, or a-Se. The TFT active readout circuit is comprised of a plurality of TFTs made from a-MO such as alloys of a-IGZO. The active device of the readout circuit may be a charge gated TFT (CGT) as shown in FIG. 1, or an active TFT configured such that a readout pulse is applied to its gate through capacitive coupling as shown in FIGS. 4-7 and 8A. The pixel sensor 900 is operated using signals applied to biasing and control terminals 930 and 940, respectively, such that the sensor value is produced at output 950.

The embodiment depicted in FIG. 10 illustrates an image sensor array 1000 comprised of a two dimensional array of image sensor pixels 900 disclosed in FIG. 9. Each horizontal row (or vertical column) is independently addressed using control signals applied to control terminal 1040, and sensor values of that row (or column) are accessed at the output of the image sensor array 1050. All image sensor pixels in a row may share a common scan line, and all image sensor pixels in a column may share a common data line.

FIG. 11A depicts an exemplary embodiment of image detector panel 1100 including image sensor array 1000 according to FIG. 10, and gate driver modules 1120 for addressing rows, and column multiplexing modules 1110 for selecting columns to read. The gate driver and column multiplexing modules are made from high mobility TFTs built on the same substrate as the image sensor array. Sensor array 1000 is a two-dimensional array of sensor pixels. Gate driver module 1120 is integrated on image detector panel 1104 and is arranged perpendicular to the rows of sensor array 1000. In FIG. 11A, gate driver module 1120 may include, for example, a-MO transistors. Gate driver module 1120 includes N outputs 1121 along the rows of sensor array 1000. Gate driver module 1120 receives a drive pulse, supply voltages, and clocks.

Multiplexing module 1110 is integrated on image detector panel 1104 and is arranged perpendicular to the columns of sensor array 1000. Multiplexing module 1110 may include, for example, a-MO transistors. Multiplexing module 1110 includes N inputs connected to the outputs 1130 of the columns of sensor array 1000. Multiplexing module 1110 also receives the supply voltages and clocks. Multiplexing module 1110 outputs sensor values to the signal processing and analog to digital conversion (ADC) modules 1180 for generating digital image information representative of the incident light on the image sensor array 1000.

FIG. 11B illustrates the output of gate driver module 1120 in response to a drive pulse. A drive pulse produces a series of sequential pulses at the outputs 1121 of the gate driver module 1120 for sequentially addressing rows of the image sensor array. As shown, a drive pulse results in a pulse at each output channel which immediately follows the output pulse of the preceding output channel. FIG. 11C illustrates an example of a gate driver module based on D-type flip-flop shift registers and pull-up/pull-down circuits which produces the response illustrated in FIG. 11B. As shown in FIG. 11C, each row includes a flip-flop 1122 and a pull-up/pull-down circuit 1123 to adjust the high and low value of the addressing pulse. The control input D of the flip-flop 1122 in the top row is connected to the drive pulse. The clock input is connected to the clock. Output Q of the flip-flop 1122 in the top row is connected to the pull-up/pull-down circuit 1123. The output of pull-up/pull-down circuit 1123 in the top row is Output 1. The output of the top row becomes the input for the row immediately below. The configuration is the same for each row with the output from one row becoming the input to the immediately following row. This configuration results in an output pulse at each row being delayed one pulse width from the row above. FIG. 11D shows an exemplary component-level implementation of a D flip-flop based on TFTs. The transistors in the D flip-flops may be high mobility TFTs, for example, TFTs formed from a-MO semiconductors.

FIG. 11E illustrates a diagram of exemplary multiplexing module 1110 that uses gate drivers 1111 and transistor switches 1112 for selecting desired columns As shown, each output of the gate driver module controls a corresponding transistor switch 1112 connecting each column of sensor array 1000 to the output 1150. When the transistor switch 1112 in a column is ON, the value of the sensor pixel at the addressed row and activated column is read out through the output 1150. An image detector panel 1104 may contain multiple gate driver modules 1120 and/or multiplexing modules 1110.

In general, each gate driver module may control multiplexing a subset of the columns in the sensor array. As one example, a sensor array having N columns may have M gate drivers each used for multiplexing K columns so that N=K*M. In this case, an address decoder 1113 is used for addressing/selecting the gate driver modules 1111. Alternatively, separate gate driver modules may control different numbers of columns depending on the total number of columns and the desired number of modules. Switching and active transistors associated with the multiplexing modules and/or gate driving modules may be made on the same panel as the sensor array using high mobility transistors such as, for example, a-MO TFTs.

FIG. 12A and FIG. 12B show two exemplary block diagrams for the signal processing and ADC unit 1180 of FIG. 11A. An active pixel sensor circuit may be read out in current mode or voltage mode, depending on how the output signal is read out. If the output signal from the pixel/panel is taken as current, the active pixel is operated in current mode, and if the output signal is taken in the form of voltage, the active pixel is operated in voltage mode. In FIG. 12A the op-amp 1182 is configured as a trans-impedance amplifier to convert the multiplexed pixel values from panel output 1150 to a voltage which is subsequently converted to a digital number by the ADC unit 1184. The input impedance of a trans-impedance amplifier is virtually zero, which guarantees that the output current of the panel will flow to the amplifier. In FIG. 12B the op-amp is configured as a voltage amplifier with the finite input impedance of Rin. In this exemplary circuit, the output of the panel is taken as the voltage and represents the voltage of the photo sensor. Additionally, the circuits may include sample and hold units, which are not shown in FIG. 12A and FIG. 12B.

### 3. Proof of Principle—Simulations

FIG. 13A depicts a graph that compares the offset noise electron simulation for a 2048×2048 pixel sensor array with a-Si passive pixel sensors, such as conventional image sensor arrays, and a-MO active pixel sensors with architectures such as the one shown in FIG. 5. In FIG. 13A, the x-axis represents the capacitance of the photodiode used in the sensor pixels, and the y-axis represents the number of offset noise electrons at the output of the array. As illustrated by FIG. 13A, the sensor array with a-MO active pixel sensors had fewer offset noise electrons compared to the array with a-Si passive pixel sensors. Also, reducing the photodiode capacitance from 3 pF to 0.5 pF reduced the noise electrons in the a-MO active pixel sensor array by approximately 2000 electrons (80 percent), whereas the noise electrons in the a-Si passive pixel array were only reduced by approximately 100 (3 percent) over the same capacitance range.

FIG. 13B depicts a graph that compares the normalized simulated transient output voltage of two sensor pixel readout circuits according to FIG. 5 read in voltage mode, one made from a-Si TFTs and the other from a-MO TFTs. In FIG. 13B, the x-axis represents the readout time in milliseconds, and the y-axis represents the output voltage of the circuit. Both circuits used 10 volts for VB2 and VB3, and a photodiode voltage of 5 volts. As shown in FIG. 13B, the output voltage of the a-MO circuit reached 99 percent of its maximum output voltage in 36 micro seconds for the simulated circuit. The output voltage of the a-Si circuit reached 99 percent of its maximum output voltage in 197 micro seconds. According to the data in FIG. 13B, the voltage mode circuit made from a-MO TFTs operates about 5 times faster than the circuit made from a-Si.

FIG. 13C depicts a graph that compares the simulated output current of two sensor pixel readout circuits according to FIG. 5, one made from a-Si TFTs and the other from a-MO TFTs, read in current mode. In FIG. 13C, the x-axis represents the voltage of the photodiode photo-sensor in the sensor pixel, and the y-axis represents the pixel output current. As shown in FIG. 13C, the a-MO circuit shows much higher current compared to that of the a-Si circuit, indicating higher gain for better detectability.

### 4. X-Ray Image Detectors and Systems

FIG. 14A represents a schematic diagram of various layers of an X-ray image detector based on the image detector panel disclosed in FIG. 11A. As shown in FIG. 14A, a scintillator layer converts X-ray quanta to optical photons, and optical photons are converted to electric charge by photodiode layer, which is then converted to digital image information by, for example, the TFT back plane (including the readout circuits, gate drivers and signal multiplexers) and the signal processing and ADC modules as described in FIGS. 11A-E. The substrate may be glass or rugged materials such as plastics or metals. The detector panel has an air-tight and light-tight encapsulating layer that protects the scintillator and sensor array from ambient light and possible degrading chemicals and moisture. The power and control unit provides power and driving signals for operation and control of the image detector and signal processing unit.

FIG. 14B shows a schematic diagram of various layers of another embodiment of an X-ray image detector based on the image detector panel disclosed in FIG. 11A. In contrast to the detector illustrated in FIG. 14A, the detector in FIG. 14B includes a photoconductor layer that converts X-ray quanta directly to electric charge without first converting the X-ray quanta to optical photons. The electric charge is converted to digital image information by the TFT back plane (including the readout circuits, gate drivers and signal multiplexers) and the signal processing and ADC modules. The substrate can be glass or rugged materials such as, for example, plastics or metals. The detector panel has an air-tight and light-tight encapsulating layer that protects the scintillator and sensor array from ambient light and possible degrading chemicals such as moisture. The power and control unit provides power and driving signals for operating and control of the image detector and signal processing unit.

The foregoing descriptions of specific embodiments have been presented for purposes of illustration and description. They are not intended to be exhaustive or to limit the invention to the precise forms disclosed, and it should be understood that many modifications and variations are possible in light of the above teaching.

We claim:

1. A sensor pixel comprising:
a detector; and
a readout circuit operatively coupled to the detector, wherein the readout circuit includes at least one charge-gated thin film transistor formed from an amorphous metal oxide alloy semiconductor.

2. The sensor pixel of claim 1, wherein the at least one charge-gated thin film transistor is configured in active mode to amplify a signal representative of a signal produced by the detector.

3. The sensor pixel of claim 1, wherein the detector is an organic photodiode or an amorphous silicon (a-Si) photodiode, or a photo sensor formed from a material selected from the group consisting of mercuric iodide (HgI), cadmium telluride (CdTe), and amorphous selenium (a-Se).

4. The sensor pixel of claim 1, wherein the readout circuit includes a pixel output terminal, and wherein the sensor pixel is configured to generate, at the pixel output terminal, a pixel signal representative of a signal produced by the detector.

5. The sensor pixel of claim 1, wherein the at least one charge-gated thin film transistor is configured to generate a transistor output signal representative of the signal produced by the detector in response to an input signal applied to a voltage gate of the at least one charge-gated thin film transistor.

6. The sensor pixel of claim 1, wherein the readout circuit comprises:
a first node; and
a switch transistor,
wherein a first node signal at the first node is transferred to a charge gate of the at least one charge-gated thin film transistor in response to the switch transistor being switched on.

7. The sensor pixel of claim 1, wherein the at least one charge-gated thin film transistor is formed from amorphous indium gallium zinc oxide (a-IGZO).

8. A sensor pixel comprising:
a detector; and
a readout circuit operatively coupled to the detector, comprising:
at least one thin film transistor formed from an amorphous metal oxide alloy semiconductor; and
a coupling capacitor being responsive to an input signal which causes the at least one thin film transistor to generate a transistor output signal representative of a signal produced by the detector.

9. The sensor pixel of claim 8, wherein the at least one thin film transistor is configured in active mode to amplify the signal representative of the signal produced by the detector.

10. The sensor pixel of claim 8, wherein the detector is an organic photodiode or an amorphous silicon (a-Si) photodiode, or a photo sensor formed from a material selected from the group consisting of mercuric iodide (HgI), cadmium telluride (CdTe), and amorphous selenium (a-Se).

11. The sensor pixel of claim 8, wherein the readout circuit includes a pixel output terminal, and wherein the sensor pixel is configured to generate, at the pixel output terminal, a pixel signal representative of the signal produced by the detector.

12. The sensor pixel of claim 8, wherein the readout circuit comprises:
a first node; and
a first switch transistor,
wherein a first node signal at the first node is transferred to a gate of the at least one thin film transistor in response to the first switch transistor being switched on.

13. The sensor pixel of claim 8, wherein the readout circuit further comprises a second switch transistor, wherein the second switch transistor is configured to transfer the transistor output signal to the pixel output terminal in response to the second switch transistor being turned on.

14. The sensor pixel of claim 8, wherein the at least one thin film transistor is formed from amorphous indium gallium zinc oxide (a-IGZO).

15. A sensor array comprising:
a plurality of sensor pixels, each sensor pixel comprising:
a detector; and
a readout circuit operatively coupled to the detector, the readout circuit comprising:
at least one charge-gated thin film transistor formed from an amorphous metal oxide alloy semiconductor; or
at least one thin film transistor formed from an amorphous metal oxide alloy semiconductor and a coupling capacitor being responsive to an input signal which causes the at least one thin film transistor to generate a transistor output signal representative of the signal produced by the detector,
wherein the readout circuit includes a pixel output terminal, and wherein the sensor pixel is configured to generate, at the pixel output terminal, a pixel signal representative of a signal produced by the detector.

16. The sensor array of claim 15, wherein the sensor pixels are configured in a two dimensional array comprising a plurality of rows and a plurality of columns, wherein the sensor array is configured to output a pixel signal from an addressed sensor pixel at an array output terminal in response to a control signal addressing the addressed sensor pixel.

17. The sensor array of claim 15, wherein the detector is an organic photodiode or an amorphous silicon (a-Si) photodiode, or a photo sensor formed from a material selected from the group consisting of mercuric iodide (HgI), cadmium telluride (CdTe), and amorphous selenium (a-Se).

18. An image detector panel comprising:
a sensor array comprising a plurality of sensor pixels, wherein the sensor pixels are arranged in a plurality of rows and a plurality of columns, each of the sensor pixels comprising:
a detector; and
a readout circuit operatively coupled to the detector, the readout circuit comprising:
at least one charge-gated thin film transistor formed from an amorphous metal oxide alloy semiconductor; or
at least one thin film transistor formed from an amorphous metal oxide alloy semiconductor and a coupling capacitor being responsive to an input signal which causes the at least one thin film transistor to generate a transistor output signal representative of a signal produced by the detector;
at least one gate driver module operatively coupled to the sensor array and configured to address the rows; and
at least one multiplexing module operatively coupled to the sensor array and configured to select columns and to multiplex pixel signals from the sensor pixels,
wherein the at least one gate driver module comprises a plurality of gate driver module elements formed from an amorphous metal oxide alloy semiconductor, and wherein the at least one multiplexing module comprises a plurality of multiplexing module elements formed from an amorphous metal oxide alloy semiconductor.

19. The image detector panel of claim 18, wherein the gate driver module elements and the multiplexing module elements are thin film transistors formed from indium gallium zinc oxide (IGZO).

20. The image detector panel of claim 18, wherein the readout circuit comprises at least one charge-gated thin film transistor formed from amorphous indium gallium zinc oxide (a-IGZO).

21. The image detector panel of claim 18, wherein the readout circuit comprises at least one thin film transistor formed from amorphous indium gallium zinc oxide (a-IGZO).

22. The image detector panel of claim 18, wherein the detector is an organic photodiode or an amorphous silicon (a-Si) photodiode, or a photo sensor formed from a material selected from the group consisting of mercuric iodide (HgI), cadmium telluride (CdTe), and amorphous selenium (a-Se).

23. The image detector panel of claim 18, comprising a plurality of gate driver modules, wherein each of the gate driver modules is configured to address a subset of the rows of the sensor array.

24. The image detector panel of claim 18, comprising a plurality of multiplexer modules, wherein each of the multiplexer modules is configured to multiplex the sensor values from the sensor pixels in a subset of the columns of the sensor array.
